(19) United States
(12) Patent Application Publication
(10) Pub. No.: US 2012/0298166 A1
(43) Pub. Date: Nov. 29, 2012

(54) Solar Panel with Energy Efficient Bypass Diode System

(75) Inventors: Hsi Sheng Chen, Fremont, CA (US); Yu-Chih Chen, Danville, CA (US)

(73) Assignee: RFMARQ, INC., Monte Sereno, CA (US)

(21) Appl. No.: 13/114,440

(22) Filed: May 24, 2011

(51) Int. Cl. H01L 31/05; G05F 1/10

(52) U.S. Cl. 136/244; 327/538

(57) ABSTRACT

A solar panel including N panel sections and individual bypass diodes for each panel section includes a panel bypass diode connected in parallel with and in opposite polarity to the solar panel. The solar panel may further include one or more group bypass diodes when the solar panel includes three or more panel sections. Each group bypass diode is connected across a group of M adjacent panel sections, M being selected from 2 to N−1. The group bypass diode is connected in parallel with and in opposite polarity to the group of M adjacent panel sections. A group bypass diode is fully forward biased to conduct current through the solar panel when the associated group of M adjacent panel sections experience performance degradation. The panel bypass diode is fully forward biased to conduct current through the solar panel when the N panel sections experience performance degradation.

### FIELD OF THE INVENTION

The invention relates to solar panels and, in particular, to a system and a method for improving energy efficiency of bypass diodes installed in solar panels.

### DESCRIPTION OF THE RELATED ART

A solar panel, also referred to as a photovoltaic panel, a solar module, or a photovoltaic module, is a packaged interconnected assembly of solar cells (also referred to as “solar wafers” or “photovoltaic cells”). FIG. 1(a) illustrates a conventional solar panel 1 including an assembly of solar cells 2 interconnected in a two-dimensional array. Solar panels use light energy (photons) from the sun to generate electricity through photovoltaic effect (i.e., the photo-electric effect). In a solar panel, the solar cells are connected electrically in series and in parallel to generate the desired output voltage and output current. More specifically, solar cells in a solar panel are connected in series to create an additive voltage and connected in parallel to yield a higher current.

FIG. 1(b) illustrates a single solar cell 2 including two bus bars 3 forming the electrical contacts of the solar cell. Solar cell 2 includes bus bars 3 formed on the front side (sun up) and also the back side (not shown) of the solar cell. Solar cells 2 are connected in series to form a column of the solar panel 1 by connecting the bus bars on the front side of one solar cell to the bus bars on the back side of the next solar cell and so on. Conductive wires or traces connect the bus bars at the ends of the columns of solar cells to form a serial or parallel connection from the columns of solar cells.

FIG. 2 illustrates a typical solar panel. Referring to FIG. 2, a solar panel 10 includes an assembly of a two-dimensional array of interconnected solar cells 12. In the present illustration, each solar cell 12 includes two conductive traces (bus bars) 14 formed on the front side and two conductive traces (bus bars) formed on the back side (not shown) of the solar cell. In the present illustration, the conductive traces 14 are connected from the front of one solar cell to the back of an adjacent solar cell in a column to form a serial connection of solar cells in a vertical column. Furthermore, in the present illustration, the bus bars 14 are connected at the ends of the solar panel 10 to form a serial connection of solar cells across the four columns. Other combinations of solar cells, including serial or parallel combinations, are also possible by connecting the bus bars in the desirable manner. Solar panel 10 includes external connectors 16 and 18 for connecting to the most positive node (the Anode) and the most negative node (the Cathode) of the solar panel. The solar cells may be divided into sections, such as each column of cells may belong to one panel section.

In addition, the solar panel 10 further includes an electrical junction box for housing the electrical connectors to the anode and cathode terminals of the solar panel. The junction box is typically formed on the backside of the solar panel and is not shown in FIG. 2.

Because a single solar panel can only produce a limited amount of power, most photovoltaic installations involve connecting multiple solar panels into an array. A photovoltaic system or a solar system typically includes an array of solar panels, an inverter, batteries and interconnection wiring. Solar panels are interconnected, in series or parallel, or both, to create a solar array providing the desired peak output voltage and output current.

When all the solar panels in a solar array are functioning, the solar array supplies a given amount of output current I_{S} which is delivered to a load as the load current I_{Load}. More specifically, the solar array output current I_{S} flows from the anode of the solar power system (the positive terminal) to the load and the current then returns to the cathode of the solar power system (the negative terminal). In the solar array, the solar panel output current flows from the cathode terminal to the anode terminal of each solar panel. The load may demand a load current I_{Load} that is less than or equal to the maximum current generating capability of the solar cells.

One of the lifetime-limiting factors for solar panels is hot spots that may be formed on a panel. Hot spots on a solar panel may limit the panel's lifetime by causing damage to the solar cells or interconnections due to the heat generated by the hot spots. Hot spots can also cause longer term degradation of the solar cell material. While some causes of solar panel hot spots are manufacturing related, other causes are beyond the control of the solar panel manufacturer. For example, some solar cells in a solar panel may be exposed to more or less sunlight than other solar cells due to partial shade, dirt or bird droppings in a localized area. When one or more solar cells experiences performance degradation, a reduction in the current generating ability at the degraded solar cells results. To keep up with the higher current demanded by the load, the degraded solar cells become reverse biased which leads to dissipation of a large amount of power generated by the normal solar cells. The power dissipation, in the form of heat, leads to “hot spot” formation in the solar panel, with the potential to cause permanent damage to the solar panel.

One solution currently used to address the solar panel hot spot issue is to install a bypass diode between the anode and cathode terminals of the solar panel. FIG. 3 is a schematic diagram illustrating the equivalent circuit of a series of solar panels each with a bypass diode connected thereto. Referring to FIG. 3, a solar array 20 includes three solar panels connected in series between the anode terminal 22 and the cathode terminal 24. A bypass diode is connected in parallel, but with opposite polarity, to each solar panel. For instance, a diode D1 is connected in parallel but with opposite polarity to solar panel 1. That is, the cathode of diode D1 is connected to the anode of the solar panel 1 and the anode of the diode D1 is connected to the cathode of the solar panel 1. The same bypass diode connection is made for diodes D2 and D3. The bypass diode is typically installed between the cathode and anode terminals of the solar panel in the junction box of the solar panel.

The bypass diode (D1, D2 or D3) is connected in such a way that the bypass diode is reverse biased when the solar panel is functioning normally and all the solar cells are capable of generating enough current for the load. Thus, under normal operation, each solar panel is forward biased and therefore the bypass diode is reverse biased and is effectively an open circuit. The solar array output current I_{S} flows through solar array 20 from the cathode terminal 24 to the anode terminal 22 via a current path 26 through solar panels 1, 2 and 3. However, if a solar panel or a portion of a solar panel (e.g. solar panel 2) becomes unable to generate enough current to meet the load current demand, such as because the solar panel is damaged or is shaded from the sun, the affected solar panel (solar panel 2) becomes reverse biased and the associated bypass diode (D2) becomes forward biased and conducts current, thereby allowing excessive current from the normally functioning solar panel 3 to flow in the bypass diode circuit (current path 28) to solar panel 1. In this manner, the degraded solar panel 2 is bypassed. The maximum reverse bias voltage across the degraded solar panel is reduced by the bypass diode D2 to about a single diode voltage drop, thus limiting the current flow through the degraded solar panel 2 and preventing hot-spot heating at the degraded solar panel.

When a single bypass diode is used, the entire solar panel is bypassed even though only one or a few solar cells in the panel may be defective or degraded. In some cases, the solar panel is partitioned into two or more sections and each panel section is provided with its own bypass diode. In this manner, when only a portion of the solar cells in a panel section experience performance degradation, the other panel sections with all normally functioning solar cells may continue to produce electricity. FIG. 4 is a schematic diagram illustrating the equivalent circuit of a solar panel with panel sections where each section has a bypass diode connected thereto. Referring to FIG. 4, a solar panel 30 is divided into three panel sections 1, 2 and 3 between the anode terminal 32 and the cathode terminal 34. A bypass diode (D1, D2 or D3) is connected across the most positive and most negative nodes of each panel sections 1, 2 or 3.

When the solar panel is functioning normally and capable of generating current demanded by the load, diodes D1, D2 and D3 are reverse biased and the solar panel output current flows through the solar cells in panel sections 1, 2 and 3. However, when one or more solar cells in a section of the solar panel malfunctions or underperforms, that panel section becomes reverse biased. In that case, the associated bypass diode becomes forwarded biased to provide an alternate current path for the panel output current. That is, the excess output current not supported by the underperforming panel section bypasses the underperforming panel section and flows through the bypass diode. Accordingly, the solar panel is capable of supporting the load current demand, despite one or more solar cells in the panel underperforming. The bypass diodes are typically installed between the cathode and anode terminals and panel section contact pads in the junction box of the solar panel.

The use of bypass diodes allow excess solar panel output current to bypass an underperforming solar panel in a solar array or an underperforming section of solar cells in a solar panel so that the desired peak output current level of the solar system can be maintained. However, when the bypass diodes are forward biased and conducts the current from the normally functioning solar panels or solar panel sections, the forward biased bypass diode can dissipate considerable amount of power. Power dissipation at the bypass diodes results in significant heating of the diode devices and also results in temperature increase in the junction box housing. In the case of a solar panel with multiple panel sections and multiple bypass diodes, such as solar panel 30 of FIG. 4, significant heating of the bypass diodes can result when multiple panel sections suffer from performance degradation and multiple bypass diodes are forward biased. The high temperature in the junction box resulted from the power dissipation of the forward biased bypass diodes leads to reliability issues. Also, power dissipation at the bypass diodes reduces the efficiency of the solar panel.

To alleviate overheating of the bypass diodes, some solar panel implements the bypass diode using two or more diodes connected in parallel, as shown in FIG. 5. The parallel connection of two diodes (e.g. diode D1A and D1B) across a panel section has the effect of spreading the heat generated by the power dissipation among the two diodes so that each diode (D1A or D1B) experiences less heating. However, the total power dissipation is not reduced and the efficiency of the solar panel is not improved.

### SUMMARY OF THE INVENTION

According to one embodiment of the present invention, a solar panel including N panel sections connected in series between an anode terminal and a cathode terminal where N is two or more and each panel section includes one or more solar cells and has an individual bypass diode connected in parallel with and in opposite polarity to the respective panel section includes a panel bypass diode connected between the anode terminal and the cathode terminal of the solar panel where the panel bypass diode is connected in parallel with and in opposite polarity to the solar panel. In operation, the panel bypass diode is fully forward biased by one diode voltage to conduct current through the solar panel when the N panel sections experience performance degradation.

In another embodiment, the solar panel further includes one or more group bypass diodes when the solar panel includes three or more panel sections where each group bypass diode is connected across a group of M adjacent panel sections, M being selected from 2 to N−1. The group bypass diode is connected in parallel with and in opposite polarity to the group of M adjacent panel sections. In operation, each of the one or more group bypass diodes is fully forward biased by one diode voltage to conduct current through the solar panel when the associated group of M adjacent panel sections experience performance degradation.

According to another aspect of the present invention, a method in a solar panel to reduce power dissipation in bypass diodes is described. The solar panel includes N panel sections connected in series between an anode terminal and a cathode terminal, N being two or more, and each panel section includes one or more solar cells and has an individual bypass diode connected in parallel with and in opposite polarity to the respective panel section. The method includes connecting a panel bypass diode between the anode terminal and the cathode terminal of the solar panel where the panel bypass diode is connected in parallel with and in opposite polarity to the solar panel. The method further includes forward biasing the panel bypass diode by one diode voltage to conduct current through the solar panel when the N panel sections experience performance degradation.

In another embodiment, a method further includes providing one or more group bypass diodes when the solar panel includes three or more panel sections where each group bypass diode is connected across a group of M adjacent panel sections, M being selected from 2 to N−1, and the group bypass diode is connected in parallel with and in opposite polarity to the group of M adjacent panel sections. The method further includes forward biasing each of the one or more group bypass diodes by one diode voltage to conduct current through the solar panel when the associated group of M adjacent panel sections experience performance degradation.

The present invention is better understood upon consideration of the detailed description below and the accompanying drawings.

### BRIEF DESCRIPTION OF THE DRAWINGS

FIG. 1(a) illustrates a conventional solar panel including an assembly of solar cells interconnected in a two-dimensional array.

FIG. 1(b) illustrates a single solar cell including two bus bars forming the electrical contacts of the solar cell.

FIG. 2 illustrates a typical solar panel.

FIG. 3 is a schematic diagram illustrating the equivalent circuit of a series of solar panels each with a bypass diode connected thereto.

FIG. 4 is a schematic diagram illustrating the equivalent circuit of a solar panel with panel sections where each section has a bypass diode connected thereto.

FIG. 5 is a schematic diagram illustrating the equivalent circuit of a solar panel with panel sections where each section has a bypass diode formed by the parallel connection of two diodes.

FIG. 6 is a schematic diagram illustrating the equivalent circuit of a solar panel implementing the energy efficient bypass diode system and method according to one embodiment of the present invention.

FIG. 7 is a schematic diagram illustrating the equivalent circuit of a solar panel with two panel sections and implementing the energy efficient bypass diode system and method according to one embodiment of the present invention.

FIG. 8 is a schematic diagram illustrating the equivalent circuit of a solar panel with three panel sections and implementing the energy efficient bypass diode system and method according to one embodiment of the present invention.

FIG. 9 is a schematic diagram illustrating the equivalent circuit of a solar panel with four panel sections and implementing the energy efficient bypass diode system and method according to one embodiment of the present invention.

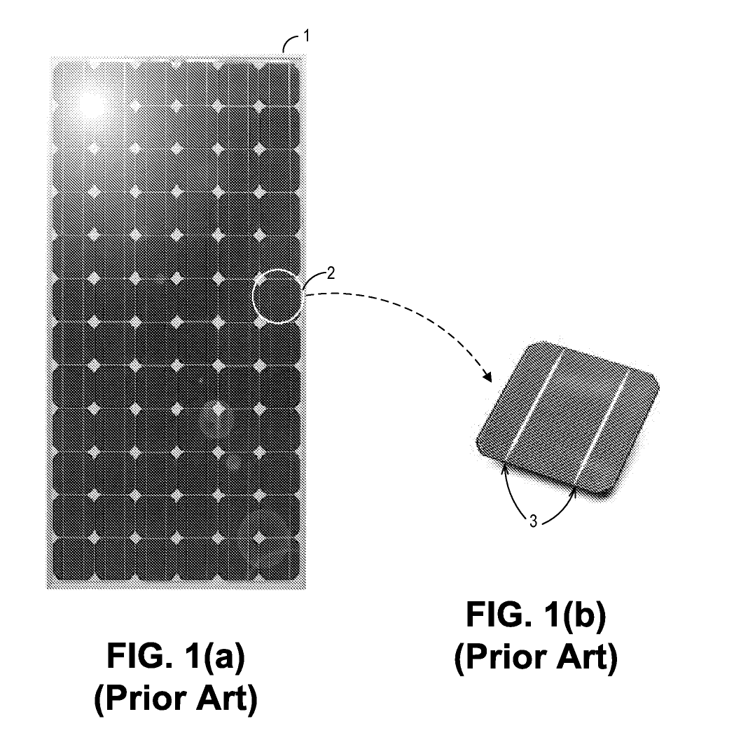

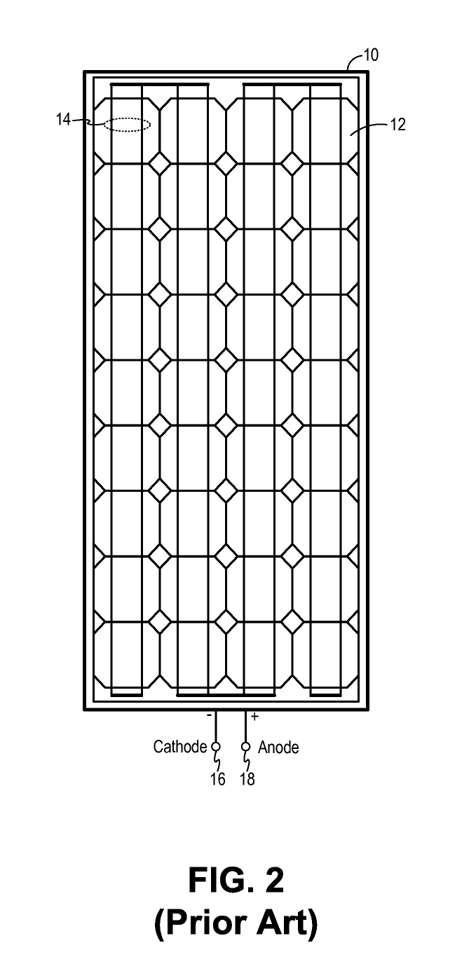

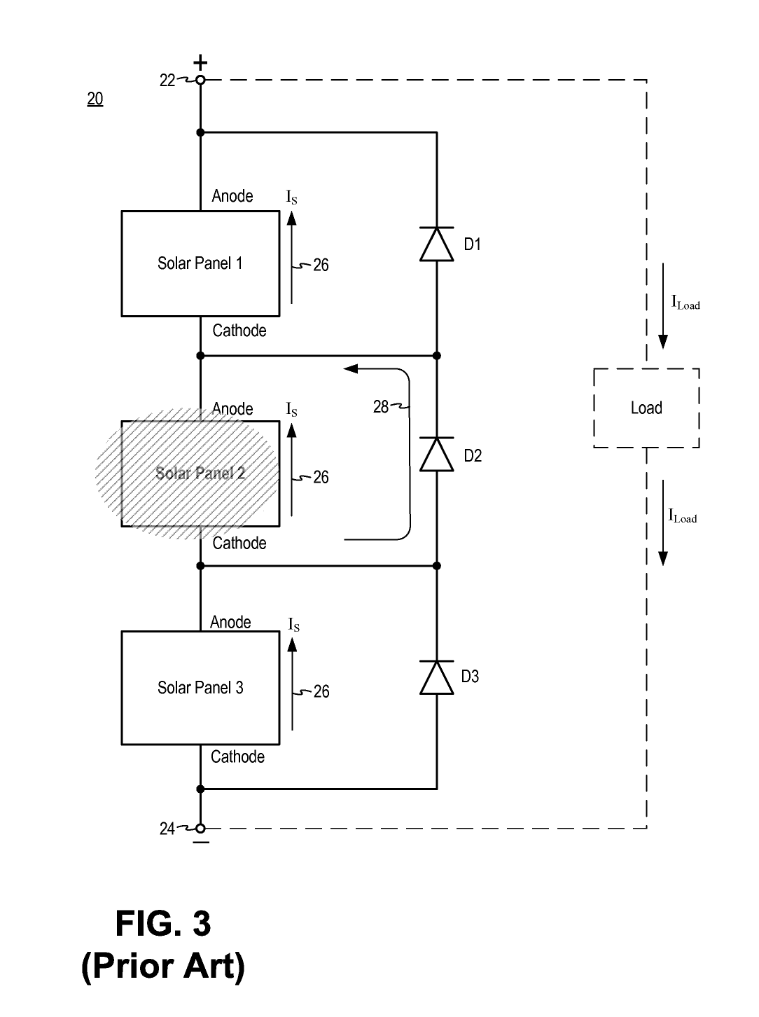

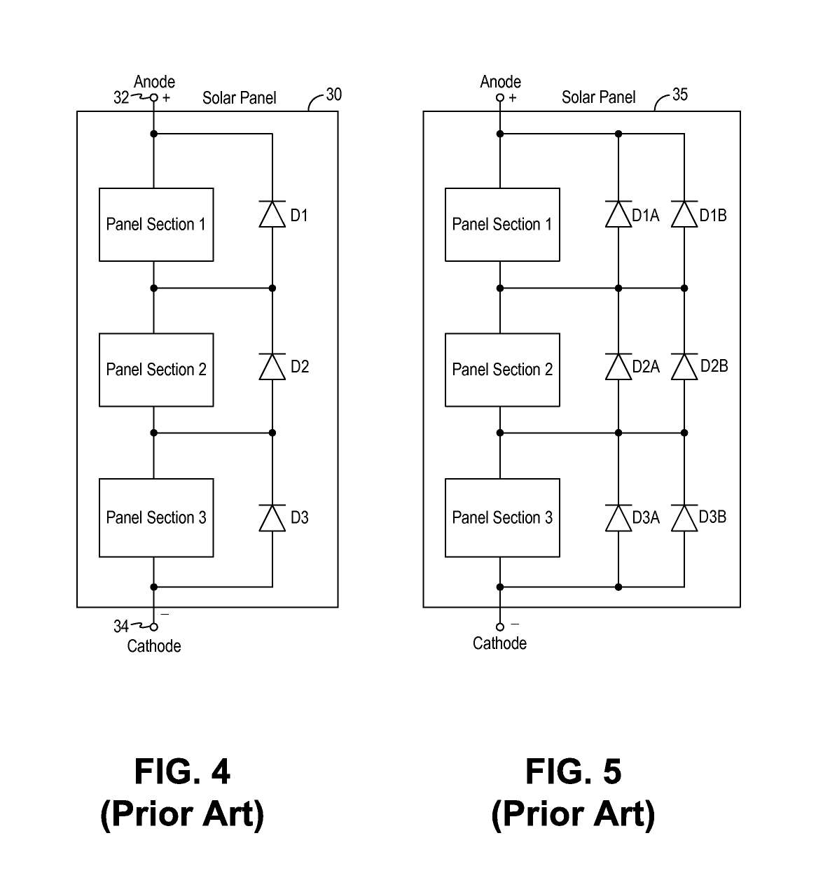

### DETAILED DESCRIPTION OF THE PREFERRED EMBODIMENTS

According to one aspect of the present invention, a system and method to reduce power dissipation at solar panel bypass diodes and improve the energy efficiency of a solar panel with multiple panel sections includes coupling a panel bypass diode across the anode and cathode terminals of the solar panel and coupling one or more group bypass diodes to groups of adjacent panel sections, when the solar panel includes three or more panel sections. In this manner, when two or more adjacent panel sections in a solar panel experience performance degradation, the panel bypass diode or the group bypass diode is forwarded biased to provide a current path to bypass the degraded panel sections, instead of allowing the current to flow through the individual bypass diode coupled to each individual panel section. As a result, a fewer number of bypass diodes is forward biased and conducting currents when multiple adjacent panel sections experience performance degradation so that the power dissipation and heat generation at the bypass diodes can be significantly reduced.

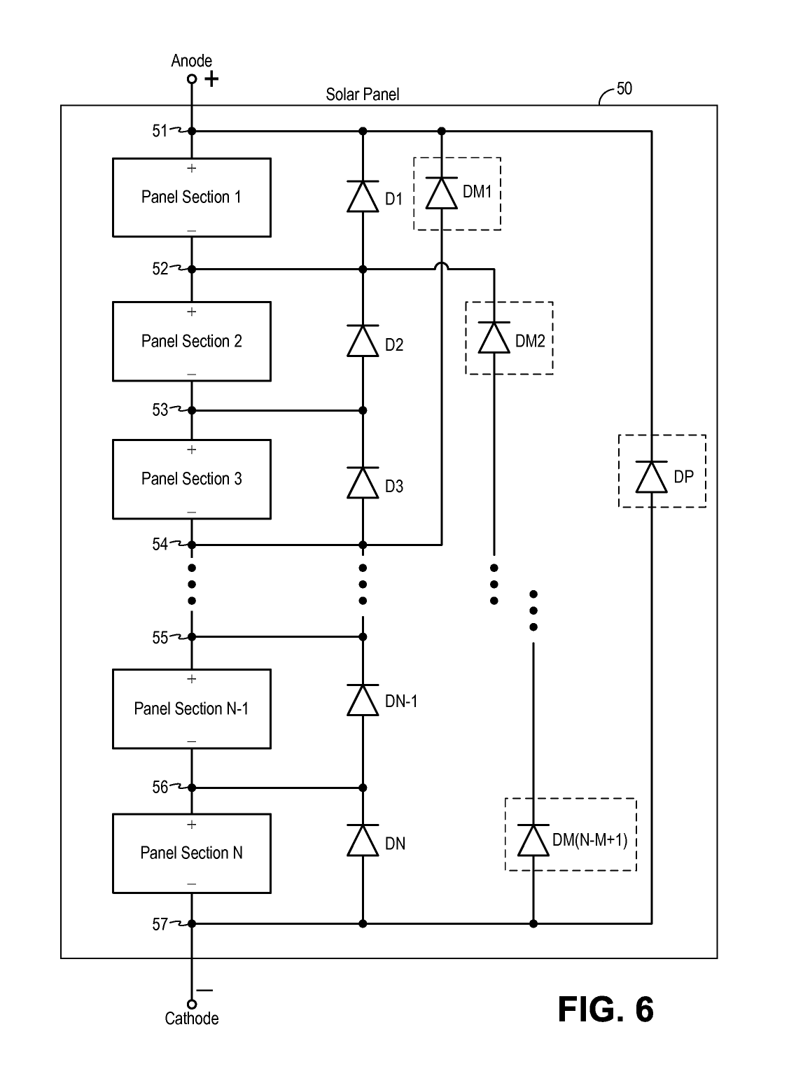

FIG. 6 is a schematic diagram illustrating the equivalent circuit of a solar panel implementing the energy efficient bypass diode system and method according to one embodiment of the present invention. Referring to FIG. 6, a solar panel 50 includes multiple solar cells connected in series and/or in parallel between the anode terminal 51 and the cathode terminal 57. The solar cells in solar panel 50 are partitioned into N panel sections (panel section 1, 2, 3 . . . N), where N is an integer of two or more. The N panel sections are connected in series between the anode terminal 51 and the cathode terminal 57. A bypass diode (D1, D2, D3 . . . DN) is connected across the most positive and most negative nodes of each panel sections 1 to N. More specifically, each bypass diode is connected in parallel with but in opposite polarity to each panel section. That is, the cathode of the individual bypass diode is connected to the most positive node of the panel section while the anode of the individual bypass diode is connected to the most negative node of the panel section. Bypass diodes D1 to DN are referred to herein as “individual bypass diodes” as they are associated with individual panel sections 1 to N. In FIG. 6, individual bypass diodes D1 to DN are illustrated as being a single diode. In other embodiments, each individual bypass diodes Dl to DN may be formed by the parallel connection of two or more diodes. As described above, providing an individual bypass diodes D1 to DN allow the solar panel output current to bypass a panel section that may be underperforming, so that the overall output current of the solar panel is not affected when some but not all of the solar cells have degraded performances, such as due to shading. However, when multiple panel sections experience performance degradation, multiple individual bypass diodes will become forward biased to conduct the bypass current. Heat dissipation by the multiple forward biased individual bypass diodes become a significant reliability problem for the solar panel.

According to embodiments of the present invention, the solar panel 50 implements an energy efficient bypass diode system. In embodiments of the present invention, a panel bypass diode DP is added to solar panel 50 and is connected across the anode terminal 51 and the cathode terminal 57. More specifically, the panel bypass diode DP is connected in parallel, but with opposite polarity, to the solar panel 50. That is, the cathode of panel bypass diode DP is connected to the anode terminal 51 of the solar panel while the anode of panel bypass diode DP is connected to the cathode terminal 57 of the solar panel. The panel bypass diode DP provides a current path for the output current generated by another solar panel that is connected to solar panel 50 to form a solar array. The panel bypass diode DP allows the output current to bypass solar panel 50 all together in the event that all of the panel sections 1 to N of solar panel 50 degrades or malfunctions. In this manner, when all of the panel sections in a solar panel degrades, only one bypass diode, diode DP, is forward biased and conducting current. In the conventional solar panel, all N individual bypass diodes would be forward biased and conducting currents. The panel bypass diode DP thus provides (N−1)/N amount of reduction in power dissipation.

In addition to the panel bypass diode, when the solar panel includes three or more panel sections, one or more group bypass diodes are also added to the solar panel. Each group bypass diode is connected across a group of M adjacent panel sections, where M is an integer from 2 to N−1. More specifically, each group bypass diode is connected in parallel with but in opposite polarity to the most positive and most negative nodes of the group of M adjacent panel sections. That is, the cathode of the group bypass diode is connected to the most positive node of the group of M adjacent panel sections while the anode of the group bypass diode is connected to the most negative node of the group of M adjacent panel sections.

For instance, in solar panel 50, a set of group bypass diodes is added between each group of three adjacent panel sections. More specifically, a group bypass diode DM1 is coupled across panel sections 1 to 3 (nodes 51 and 54). Group bypass diode DM1 is connected in parallel, but with opposite polarity, to the group of panel sections 1 to 3. Another group bypass diode DM2 is coupled across panel section 2 (node 52) to panel section 4 (not shown) in the same parallel but opposite polarity manner. The last group bypass diode DM(N−M+1) is coupled across the last three panel sections: panel section N−2 (not shown), panel section N−1 and panel section N. In this manner, when a group of adjacent panel sections becomes degraded, instead of fully forward biasing the individual bypass diodes of each panel section, the group bypass diode for that group of panel sections is fully forward biased to carry the output current around the degraded group of panel sections. The use of the group bypass diodes realize a reduction in power dissipation of (M−1)/M.

Under normal operation, when the solar panel 50 is functioning and all solar cells are performing at the desired level, all of the bypass diodes, including individual bypass diodes D1 to DN, panel bypass diode DP and group bypass diodes DM1 to DM(N−M+1), are reverse biased and the solar panel output current flows through the solar cells in panel sections N to 1. However, one or more solar cells or the entire solar panel may experience performance degradation over the course of the energy generation operation. A solar cell or a solar panel may experience performance degradation when the solar cell or solar panel becomes defective or suffers from device failure. A solar cell or a solar panel may also be experiencing performance degradation or underperforming when the solar cell or solar panel experiences temporary performance degradation, such as due to shading of all or part of the solar panel.

When one or more solar cells in a panel section of the solar panel malfunctions or underperforms, that panel section becomes reverse biased. In that case, the individual bypass diode (D1 to DN) associated with the specific panel section becomes forward biased to provide an alternate current path for the panel output current. That is, the excess output current not supported by the underperforming panel section bypasses the underperforming panel section and flows through the individual bypass diode (D1 to DN).

However, when two or more adjacent panel sections malfunction or underperform, the group bypass diode and/or the panel bypass diode becomes effective in providing an alternate current path which bypasses the individual bypass diodes. When two or more adjacent panel sections malfunction, the associated group bypass diode become fully forward biased and turned on to carry the panel output current whereas the individual bypass diodes will not be fully forward biased. In the present description, a diode is said to be “fully forward biased” when the diode is biased by one diode voltage so that the diode is fully turned on and conduct appreciable or significant amount of current. A diode may be forward biased by a voltage less than one diode voltage in which case the diode is not fully turned on and may conduct only inappreciable amount of current. In the energy efficient bypass diode system of the present invention, when two or more adjacent panel sections malfunction, the associated group bypass diode become fully forward biased by one diode voltage drop. The serially connected string of individual bypass diodes is connected in parallel with the group bypass diode. The individual bypass diodes will become forward biased. However, each individual bypass diode is biased by only a portion of the one diode voltage that is applied across the group bypass diode, hence the individual bypass diodes are not fully forward biased.

For example, in solar panel 50, when adjacent panel sections 1-3 are all underperforming, instead of fully forward biasing each of the three individual bypass diodes D1 to D3, resulting in one diode voltage across each of the panel sections, the associated group bypass diode DM1 is fully forward biased by one diode voltage between nodes 51 and 54. The group bypass diode DM1 is turned on to carry the output current for all three panel sections. The serially connected string of individual bypass diodes D1 to D3 has the one diode voltage imposed across the string (nodes 51 and 54). Thus, each individual bypass diode D1 to D3 experiences only a portion of the one diode voltage and the individual bypass diodes D1 to D3 are thus not fully forward biased and they conduct very little current. Accordingly, when adjacent panel sections 1-3 are all underperforming, only one group bypass diode is fully forward biased to conduct current instead of three individual bypass diodes and significant reduction in power dissipation at the bypass diodes is achieved.

Finally, in the event that all N panel sections are underperforming, the panel bypass diode DP is fully forward biased to conduct the output current from the cathode terminal 57 to the anode terminal 51, bypassing the solar cells in solar panel 50 all together. The panel bypass diode DP eliminates the situation where all N of the individual bypass diodes D1 to DN are fully forward biased and conducting currents when all N panel sections underperforms, such as when the entire solar panel becomes shaded. The N individual bypass diodes may become forward biased but by a voltage much less than the one diode voltage so that the N individual bypass diodes conduct inappreciable amount of current.

Accordingly, the solar panel 50 is capable of supporting the load current demand, despite one or more solar cells in the panel underperforming. More importantly, power dissipation in the bypass diodes of the solar panel 50 is reduced and the efficiency of solar panel 50 is improved.

In embodiments of the present invention, the bypass diodes (including individual bypass diodes, group bypass diodes and the panel bypass diode) are installed between the cathode and anode terminals and panel section contact pads in the junction box of the solar panel 50. In other embodiments, the bypass diodes are integrated with the solar cell and formed inside the solar panel. In yet another embodiment, the bypass diodes are installed in an assembly electrically connected to the interconnected solar cells or solar panel sections. Other ways to electrically connect the bypass diodes to the panel sections are possible.

In the above-described embodiments, the solar panel is described as being partitioned into two or more panel sections, each section containing multiple solar cells and each section associated with an individual bypass diode. In other embodiments, the solar panel may be provided with an individual bypass diode for each solar cell. In that case, a panel section can be taken as including a single solar cell. A group of adjacent panel sections may then be formed by a group of adjacent solar cells.

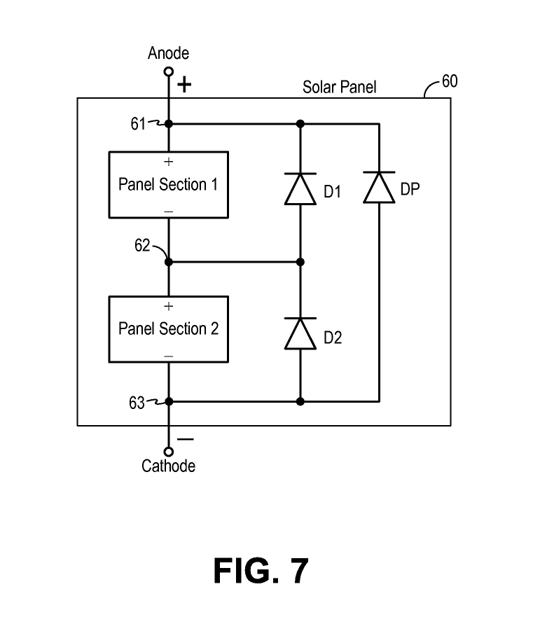

FIG. 7 is a schematic diagram illustrating the equivalent circuit of a solar panel with two panel sections and implementing the energy efficient bypass diode system and method according to one embodiment of the present invention. Referring to FIG. 7, a solar panel 60 includes two panel sections 1 and 2 connected in series between the anode terminal 61 and the cathode terminal 63. Each panel section includes an individual bypass diode Dl, D2 connected thereto in parallel but with opposite polarity. Solar panel 60 implements the energy efficient bypass diode system by coupling a panel bypass diode DP across the anode terminal 61 and the cathode terminal 63 of solar panel 60. Panel bypass diode DP is connected in parallel with but in opposite polarity to the solar panel. When both panel sections 1 and 2 experience performance degradation, instead of fully forward biasing individual bypass diodes D1 and D2, only the panel bypass diode DP is fully forward biased to carry the solar array output current from the cathode terminal 63 to the anode terminal 61. In this manner, only one bypass diode is fully forward biased and conducting current instead of two as in the conventional solar panel. A one-half reduction in power dissipation is realized.

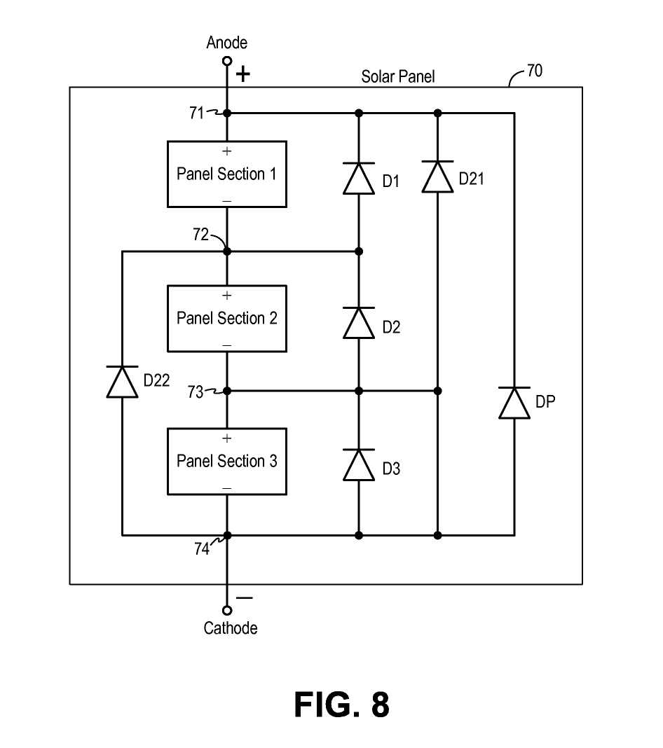

FIG. 8 is a schematic diagram illustrating the equivalent circuit of a solar panel with three panel sections and implementing the energy efficient bypass diode system and method according to one embodiment of the present invention. Referring to FIG. 8, a solar panel 70 includes three panel sections 1, 2 and 3 connected between the anode terminal 71 and the cathode terminal 74. Each panel section includes an individual bypass diode D1, D2 and D3 connected thereto in parallel but with opposite polarity. Solar panel 70 implements the energy efficient bypass diode system by coupling a panel bypass diode DP across the anode terminal 71 and the cathode terminal 74 of solar panel 70. Panel bypass diode DP is connected in parallel with but in opposite polarity to the solar panel. Solar panel 70 further includes two group bypass diodes coupled across each group of two adjacent panel sections. That is, a group bypass diode D21 is coupled across panel section 1 and panel section 2 (nodes 71 and 73). Another group bypass diode D22 is coupled across panel section 2 and panel section 3 (nodes 72 and 74).

When all panel sections 1, 2 and 3 experience performance degradation, instead of fully forward biasing the three individual bypass diodes D1, D2 and D3, only the panel bypass diode DP is fully forward biased to carry the solar array output current from the cathode terminal 74 to the anode terminal 71. In this manner, only one bypass diode is fully forward biased instead of three as in the conventional solar panel. A two-third reduction in power dissipation is realized.

When a group of adjacent panel sections experience performance degradation, such as when panel sections 1 and 2 degrade or when panel sections 2 and 3 degrade, one of the group bypass diodes is forward biased to conduct current instead of the individual bypass diodes. For example, when panel sections 1 and 2 degrade, group bypass diode D21 is fully forward biased to bypass the output current while individual bypass diodes D1 and D2 are not fully forward biased. In this manner, only one bypass diode is fully forward biased instead of two as in the conventional solar panel. A one-half reduction in power dissipation is realized.

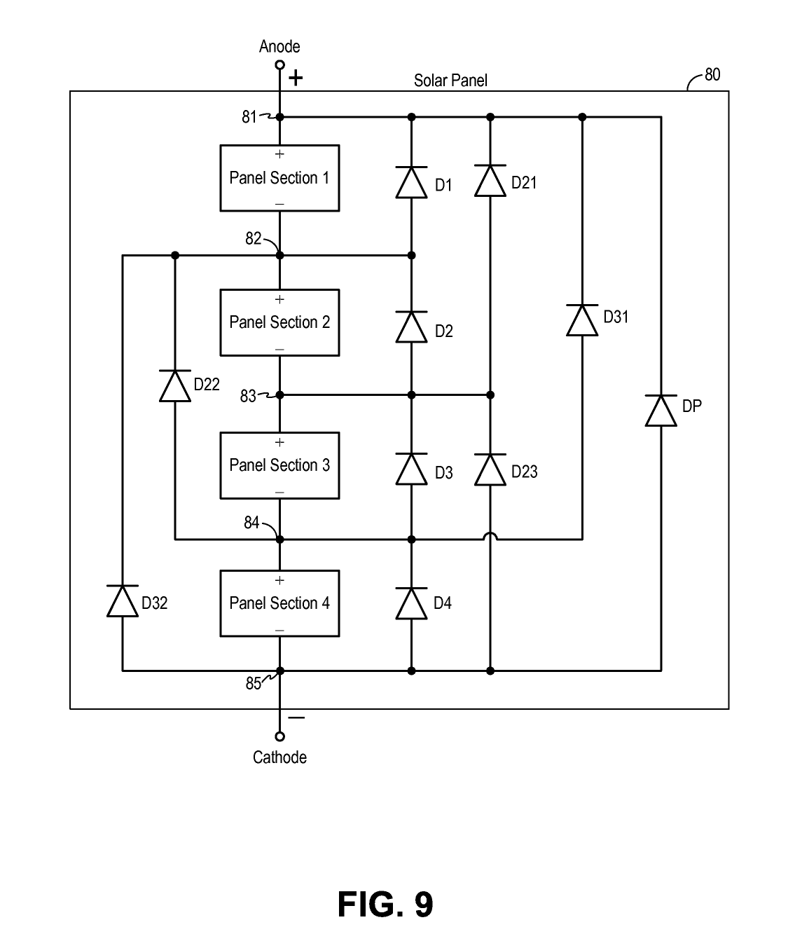

FIG. 9 is a schematic diagram illustrating the equivalent circuit of a solar panel with four panel sections and implementing the energy efficient bypass diode system and method according to one embodiment of the present invention. Referring to FIG. 9, a solar panel 80 includes four panel sections 1, 2, 3 and 4 connected between the anode terminal 81 and the cathode terminal 85. Each panel section includes an individual bypass diode D1, D2, D3 and D4 connected thereto in parallel but with opposite polarity. Solar panel 80 implements the energy efficient bypass diode system by coupling a panel bypass diode DP across the anode terminal 81 and the cathode terminal 85 of solar panel 80. Panel bypass diode DP is connected in parallel with but in opposite polarity to the solar panel.

Solar panel 80 further includes a set of group bypass diodes coupled across each group of two adjacent panel sections and another set of group bypass diodes coupled across each group of three adjacent panel sections. That is, a first group bypass diode D21 is coupled across panel section 1 and panel section 2 (nodes 81 and 83). A second group bypass diode D22 is coupled across panel section 2 and panel section 3 (nodes 82 and 84). A third group bypass diode D23 is coupled across panel section 3 and panel section 34 (nodes 83 and 85). Then, a fourth group bypass diode D31 is coupled across panel section 1 to panel section 3 (nodes 81 and 84). Finally, a fifth group bypass diode D32 is coupled across panel section 2 to panel section 4 (nodes 82 and 85).

When all panel sections 1 to 4 experience performance degradation, instead of fully forward biasing the four individual bypass diodes D1, D2, D3 and D4, only the panel bypass diode DP is fully forward biased to carry the solar array output current from the cathode terminal 85 to the anode terminal 81. In this manner, only one bypass diode is forward biased instead of four as in the conventional solar panel. A three-fourth reduction in power dissipation is realized.

When a group of adjacent panel sections experience performance degradation, such as when panel sections 1 and 2 degrade or when panel sections 2, 3 and 4 degrade, the group bypass diodes are forward biased to conduct current instead of the individual bypass diodes. For example, when panel sections 2 and 3 degrade, group bypass diode D22 is fully forward biased to bypass the output current but individual bypass diodes D2 and D3 are not fully forward biased. In this manner, only one bypass diode is fully forward biased instead of two as in the conventional solar panel. A one-half reduction in power dissipation is realized.

On the other hand, when panel sections 2 to 4 degrade, group bypass diode 32 is fully forward biased to bypass the output current but individual bypass diodes D2 to D4 are not fully forward biased. In this manner, only one bypass diode is fully forward biased instead of three as in the conventional solar panel. A two-third reduction in power dissipation is realized.

One of ordinary skill in the art, upon being apprised of the present invention, would appreciate that any combination of group bypass diodes and the panel bypass diode can be used to reduce the number of bypass diodes being fully forward biased, thereby reducing the power dissipation at the bypass diodes. FIGS. 7 to 9 are provided as exemplary embodiments of the energy efficient bypass diode system of the present invention for two, three and four panel sections. FIGS. 7 to 9 are illustrative only and are not intended to be limiting. The energy efficient bypass diode system and method of the present invention can be implemented with one or more group bypass diodes as needed to reduce the power and heat dissipation. Not all of the group bypass diodes shown in FIGS. 8 and 9 need to be implemented. In other embodiments of the present invention, a subset of the group bypass diodes in FIGS. 8 and 9 are implemented. For example, in solar panel 80, a solar panel designer may include only group bypass diodes for groups of two adjacent panel sections and not for group of three adjacent panel sections or vice versa. In other embodiments, a solar panel including five panel sections may include a first group bypass diode coupled across the first two panel sections and a second group bypass diode coupled across the last three panel sections. In yet another embodiment, a solar panel including five panel sections may include a first group bypass diode coupled across two adjacent panel sections, a second group bypass diode coupled across three adjacent panel sections, and a third group bypass diode coupled across four adjacent panel sections. Many combinations of group bypass diodes may be used within the scope and spirit of the energy efficient bypass diode system of the present invention.

In the above-described embodiments, the individual bypass diodes Dl to DN may be formed by the parallel connection of two or more diodes, in the manner illustrated in FIG. 5, to realize heat spreading among the parallel-connected diodes. According to embodiments of the present invention, each of the panel bypass diode and the group bypass diode may be formed by the parallel connection of two or more diodes to provide heat spreading functions. The energy efficient bypass diode system of the present invention may be implemented using a single diode or using a set of parallel-connected diodes as the panel bypass diode and the group bypass diode.

The above detailed descriptions are provided to illustrate specific embodiments of the present invention and are not intended to be limiting. Numerous modifications and variations within the scope of the present invention are possible. The present invention is defined by the appended claims.

We claim:

1. A solar panel including N panel sections connected in series between an anode terminal and a cathode terminal, N being two or more, each panel section including one or more solar cells and having an individual bypass diode connected in parallel with and in opposite polarity to the respective panel section, the solar panel comprising:
a panel bypass diode connected between the anode terminal and the cathode terminal of the solar panel, the panel bypass diode being connected in parallel with and in opposite polarity to the solar panel,
wherein the panel bypass diode is fully forward biased to conduct current through the solar panel when the N panel sections experience performance degradation.

2. The solar panel of claim 1, further comprising:
one or more group bypass diodes when the solar panel includes three or more panel sections, each group bypass diode being connected across a group of M adjacent panel sections, M being selected from 2 to N−1, the group bypass diode being connected in parallel with and in opposite polarity to the group of M adjacent panel sections,
wherein each of the one or more group bypass diodes is fully forward biased to conduct current through the solar panel when the associated group of M adjacent panel sections experience performance degradation.

3. The solar panel of claim 1, wherein the panel bypass diode comprises a cathode terminal coupled to the anode terminal of the solar panel and an anode terminal coupled to the cathode terminal of the solar panel.

4. The solar panel of claim 2, wherein each group bypass diode comprises a cathode terminal coupled to a most positive node of the group of M adjacent panel sections and an anode terminal coupled to the most negative node of the group of M adjacent panel sections.

5. The solar panel of claim 2, wherein the solar panel comprises four or more panel sections, the solar panel further comprises:
a first set of one or more group bypass diodes, each group bypass diode being connected across a group of M_{A} adjacent panel sections, M_{A} being selected from 2 to N−1; and
a second set of one or more group bypass diodes, each group bypass diode being connected across a group of M_{B} adjacent panel sections, M_{B} being selected from 2 to N−1 and being different from M_{A}.

6. The solar panel of claim 1, wherein the individual bypass diodes and the panel bypass diode are formed in a junction box of the solar panel.

7. The solar panel of claim 1, wherein the individual bypass diodes and the panel bypass diode are formed integrated with one or more solar cells in the solar panel.

8. The solar panel of claim 1, wherein the individual bypass diodes and the panel bypass diode are formed in an assembly electrically connected to one or more solar cells or one or more panel sections of the solar panel.

9. The solar panel of claim 2, wherein the individual bypass diodes, the panel bypass diode and the one or more group bypass diode are formed in a junction box of the solar panel.

10. The solar panel of claim 2, wherein the individual bypass diodes, the panel bypass diode and the one or more group bypass diode are formed integrated with one or more solar cells in the solar panel.

11. The solar panel of claim 2, wherein the individual bypass diodes, the panel bypass diode and the one or more group bypass diode are formed in an assembly electrically connected to one or more solar cells or one or more panel sections of the solar panel.

12. The solar panel of claim 1, wherein the panel bypass diode comprises two or more diodes connected in parallel.

13. The solar panel of claim 2, wherein each of the panel bypass diode and the one or more group bypass diodes comprises two or more diodes connected in parallel.

14. A method in a solar panel to reduce power dissipation in bypass diodes, the solar panel including N panel sections connected in series between an anode terminal and a cathode terminal, N being two or more, each panel section including one or more solar cells and having an individual bypass diode connected in parallel with and in opposite polarity to the respective panel section, the method comprising:
connecting a panel bypass diode between the anode terminal and the cathode terminal of the solar panel, the panel bypass diode being connected in parallel with and in opposite polarity to the solar panel; and
forward biasing the panel bypass diode to conduct current through the solar panel when the N panel sections experience performance degradation.

15. The method of claim 14, further comprising:
providing one or more group bypass diodes when the solar panel includes three or more panel sections, each group bypass diode being connected across a group of M adjacent panel sections, M being selected from 2 to N−1, the group bypass diode being connected in parallel with and in opposite polarity to the group of M adjacent panel sections; and
forward biasing each of the one or more group bypass diodes to conduct current through the solar panel when the associated group of M adjacent panel sections experience performance degradation.

16. The method of claim 14, wherein connecting a panel bypass diode between the anode terminal and the cathode terminal of the solar panel comprises:
connecting a cathode terminal to the anode terminal of the solar panel; and
connecting an anode terminal to the cathode terminal of the solar panel.

17. The method of claim 15, wherein providing one or more group bypass diodes when the solar panel includes three or more panel sections comprises:
connecting a cathode terminal to a most positive node of the group of M adjacent panel sections; and
connecting an anode terminal to the most negative node of the group of M adjacent panel sections.

18. The method of claim 15, wherein the solar panel comprises four or more panel sections, the method further comprises:
providing a first set of one or more group bypass diodes, each group bypass diode being connected across a group of M_{A} adjacent panel sections, M_{A} being selected from 2 to N−1; and
providing a second set of one or more group bypass diodes, each group bypass diode being connected across a group of M_{B} adjacent panel sections, M_{B} being selected from 2 to N−1 and being different from M_{A}.

19. The method of claim 14, wherein the panel bypass diode comprises two or more diodes connected in parallel.

20. The method of claim 15, wherein each of the panel bypass diode and the one or more group bypass diodes comprises two or more diodes connected in parallel.
